(19) United States
(12) Patent Application Publication
(10) Pub. No.: US 2026/0243584 A1
(43) Pub. Date: Aug. 20, 2026

(54) REDUNDANT MAGNETIC FIELD SENSOR ARRAY

(71) Applicant: TDK-Mikronas GmbH, Freiburg (DE)

(72) Inventor: Joerg FRANKE, Freiburg (DE)

(73) Assignee: TDK-Mikronas GmbH, Freiburg (DE)

(21) Appl. No.: 19/544,736

(22) Filed: Feb. 19, 2026

(30) Foreign Application Priority Data
Feb. 19, 2025 (DE) 10 2025 000 616.0

(51) Int. Cl. G01D 5/14; G01B 7/30; G01R 33/07; G01R 33/09

(52) U.S. Cl. CPC G01D 5/145; G01B 7/30; G01R 33/07; G01R 33/098

(57) ABSTRACT

A redundant magnetic field sensor array suitable for measuring the rotation angle of a magnetic device is provided. The magnetic device generates a magnetic field with magnetic field components in an X, a Y, and a Z direction and is rotatably mounted about an axis. The measuring device comprises at least six individual magnetic field sensors, the magnetic field sensors being designed as at least three Hall sensors and at least three Z-TMR Wheatstone bridges. Each Z-TMR Wheatstone bridge has two branches with half-bridges, and the half-bridges include at least two Z-TMR resistors connected in series. The two branches of the Z-TMR Wheatstone bridges are positioned geometrically separated within each pair of half-bridges. The half-bridges are arranged in pairs diametrically relative to the axis, and the bridge voltage taps or the bridge voltages are designed as output signals.

This nonprovisional application claims priority under 35 U.S.C. § 119(a) to German Patent Application No. 10 2025 000 616.0, which was filed in Germany on Feb. 19, 2025, and which is herein incorporated by reference.

### BACKGROUND OF THE INVENTION

### Field of the Invention

The present invention is directed towards a redundant magnetic field sensor array.

### Description of the Background Art

Non-contact measuring systems for determining a rotation angle position usually contain magnetic field sensors.

The rotational angle position of the shaft can be determined based on the orientation of a reference or transducer magnet, or the magnetic field generated by the magnet, which is arranged in particular so that it can rotate on a shaft.

Hall, TMR, GMR or AMR sensors are used as magnetic field sensors. TMR sensors are characterized by high sensitivity, while Hall sensors with lower sensitivity are characterized by high robustness and are easier to integrate in microelectronic manufacturing processes.

From the product catalog “Magnetic Sensors and Embedded Controllers”, 2023 edition at: https://product.tdk.com/de/system/files?file=dam/doc/product/sensor/brochure/tdk_magnetic_sensors_and_motor_controllers.pdf, TMR and Hall sensor-based angle sensors are known.

The sensor systems are also available in a redundant configuration in that two independent sensor ICs, each with identical Hall or TMR sensors, are integrated into one housing.

Using sensors of the same type corresponds to the level of homogeneous redundancy. Using sensors of different types, on the other hand, reaches the level of redundancy referred to as diverse or heterogeneous and increases the degree of integrity of the overall system. Especially in safety-relevant applications, for example in the field of automotive electronics, redundancy and robustness are an important requirement.

A combination of Hall and TMR sensors for the determination of a rotation angle represents a realization of a sensor system with diverse or heterogeneous redundancy.

In the state of the art, such systems are known from P.A. David et. al., https://www.electronicspecifier.com/products/sensors/enabling-new-levels-of-performance-and-safety-in-magnetic-sensors-with-xmr, among others, wherein the TMR elements in combination with the vertical Hall elements form a heterogeneously redundant sensor system.

For the TMR sensor, the configuration in a Wheatstone bridge circuit is usually known in the state of the art. A Wheatstone bridge is also known as a full bridge.

In the simplest case, two TMR resistors are connected in series in each of the two branches. In the simplest case, a TMR full bridge thus has four TMR resistors. The magnetization of the two TMR resistors of a half-bridge, which are connected in series, is rotated by 180 degrees each.

The magnetization of the TMR resistors of the two half-bridges, which are connected in parallel, also differs by 180 degrees. The bridge voltage represents the output signal and, due to this configuration, achieves high sensitivity.

Typically, two Wheatstone bridges arranged with orthogonally aligned magnetization to each other to enable a 360° resolution of the rotation angle.

The outputs of the two Wheatstone bridges thus provide two orthogonal output signals sin and cos, which, after appropriate preparation and calibration, can be used to determine the rotation angle position of a rotatable transducer by means of the arc rod function, wherein the transducer is generally a magnet, preferably a permanent magnet.

DE 10 2013 107 821 A1, which corresponds to US 2016/0169985, discloses an arrangement with two half-bridges of a TMR Wheatstone bridge arranged symmetrically around a flux concentrator element. The flux concentrator element enables the determination of a magnetic field component Z orthogonal to the one that the TMR elements detect according to their sensitive preferred plane in the X-Y plane.

EP 4 012 431 A1, which corresponds to US 2024/0027551, describes an integrable TMR element with a vertical structure consisting of several layers, each of which has a magnetization that is firmly formed in the Z direction. As a result, the TMR element has a sensitive preferred direction formed in the Z-direction and is referred to as the Z-TMR element.

DE 10 2015 101 635 A1 and US 2015/0219472 A1 disclose a combination of an axial TMR sensor and vertical Hall elements arranged in a circle. The TMR sensors measure a Z component, and the Hall sensors measure the X and Y components of the magnetic field. The output angle accuracy can be improved by calibrating the sensor system, for example, using the axial and vertical sensor data, both of which are representative of the rotational position. For example, in one embodiment, the “vertical” sensor can provide a first estimation of the rotational position, and the axial sensor can provide a second estimation or approximation of the rotational position, and the sensor system can combine the first and second estimations.

### SUMMARY OF THE INVENTION

It is therefore an object of the present invention to provide a device which advances the state of the art.

According to the subject-matter of the invention, a redundant magnetic field sensor device is provided, which is suitable for measuring an angle of rotation of a magnetic device.

The magnetic device generates a magnetic field with magnetic field components in an X and in a Y and in a Z direction and is rotatable about an axis. It should be noted that the three directions mentioned above are orthogonal to each other according to a Cartesian coordinate system.

In a further development, the magnet device comprises or consists of a magnet, in particular a permanent magnet.

The redundant magnetic field sensor device comprises a measuring device with at least six individual magnetic field sensors. The magnetic field sensors are designed as at least two Hall sensors and as at least two Z-TMR Wheatstone bridges, wherein the Hall sensors are designed as lateral Hall sensors in an X-Y plane. It should be noted that the two Z-TMR Wheatstone bridges form a total of four magnetic field sensors due to their respective arrangement in two separated branches with half-bridges.

The Z-TMR Wheatstone bridges each can have two branches with half-bridges, with each of the half-bridges having at least two Z-TMR resistors connected in series.

The two branches of the Z-TMR Wheatstone bridges can be geometrically separated in each of the two half-bridges.

The half-bridges can be arranged in pairs diametrically in relation to the axis, with a bridge voltage applied to each of the respective bridge voltage taps as an output signal.

Here, half-bridges, i.e., the Z-TMR half-bridges, can be arranged on a first circular path, with an imaginary extension of the axis preferably passing through the center of the first circle.

It should be noted that the Hall plates and the Z-TMR half-bridges each measure the Z component of the magnetic field.

It is understood that the half-bridges, which are arranged diametrically in pairs in relation to the axis, are spaced from each other and from the axis.

An advantage is that the horizontal Hall elements have a significantly better sensitivity and signal-to-noise ratio than vertical Hall elements.

Another advantage is that the heterogeneously redundant magnetic field sensor device, with its geometrically diametrically arranged Z-TMR half-bridges and the separation of the Wheatstone half-bridges, allows for both the positive and negative field components to be measured simultaneously in the given magnetic field, thus enabling a differential evaluation with suppression of a homogeneous interference field.

It should be noted that the terms “positive” and “negative” can refer to the field components, i.e., the components of the magnetic field that are magnetic field lines running in the Z direction and those running opposite to the Z direction.

In a further development, the lateral Hall sensors can be designed as Hall plates.

In an example of the redundant sensor array, the Z-TMR half-bridges and the Hall sensors are arranged concentrically around axis A in a common plane or in two planes spaced in the Z direction. Here, the planes or the plane are formed to be precisely or, as a first approximation, orthogonally to the axis, i.e., orthogonally to the Z-direction. It is understood that each type of magnetic field sensor is arranged in the same plane.

In an example of the redundant sensor array, the sensors are arranged in two different planes separately according to the type of magnetic field sensor, wherein the two planes are each formed to be precisely, or in a first approximation, orthogonally to the axis.

In a further development, the magnetic field sensors can be arranged along a single circular path. In other words, the magnet field sensors, i.e., the Hall plates and the Z-TMR resistors, alternate along the circular path.

In an example, six individual magnetic field sensors can be provided, wherein the magnetic field sensors are designed as at least three Hall sensors and as at least three Z-TMR Wheatstone bridges, and the three Z-TMR Wheatstone bridges each have two branches with half-bridges.

In another further development, a total of six magnetic field sensors can be arranged along a single circular path. In another development, four Hall sensors or six Hall sensors or eight Hall sensors and four half-bridges or six half-bridges or eight half-bridges are arranged along a circular path.

In an example of the redundant magnetic field sensor array, the half-bridges can be arranged on a first circular path with a first radius, and the Hall sensors are arranged on a second circular path with a second radius, wherein the first radius and the second radius are different.

In a further development of the redundant magnetic field sensor array, the separate, diametrically arranged pairs of half-bridges can be tapped differentially using a differential amplifier, and the bridge voltages are provided as output signals. An advantage of this lies in the integration of the sensor control and signal acquisition. A high degree of integration can be achieved, in particular on a silicon substrate manufactured using CMOS technology.

In an example, the first radius can be larger than the second radius.

In an example, the first radius and the second radius can be arranged in the same plane or, in a first approximation, in the same plane.

In an example, the half-bridges of different Z-TMR Wheatstone bridges can be immediately adjacent to each other on the first path.

In a further development, the two Z-TMR resistors of a branch connected in series have a mutually antiparallel measuring direction.

In another further development, the antiparallel measuring directions of the

Z-TMR resistors of the two branches of the respective Z-TMR Wheatstone bridge can be different from each other. It should also be noted that the Z-TMR resistors are formed in the Z direction.

In an example, the branches of the Z-TMR Wheatstone bridges can be connected to inputs of a differential amplifier.

The distance between the two half-bridges of a branch arranged diametrically on the first circle can be in a range between 0.2 mm and 10 mm or is greater than 0.2 mm.

The distance between the two half-bridges of a branch arranged diametrically on the first circle can be five times greater than the extension of one of the half-bridge elements in the direction of the respective longest extension.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a view of a first example,

FIG. 2 is a view of an expanded example,

FIG. 3 is a view of an example,

FIG. 4 is a detailed view of the example, and

FIG. 5 is a view showing an arrangement.

### DETAILED DESCRIPTION

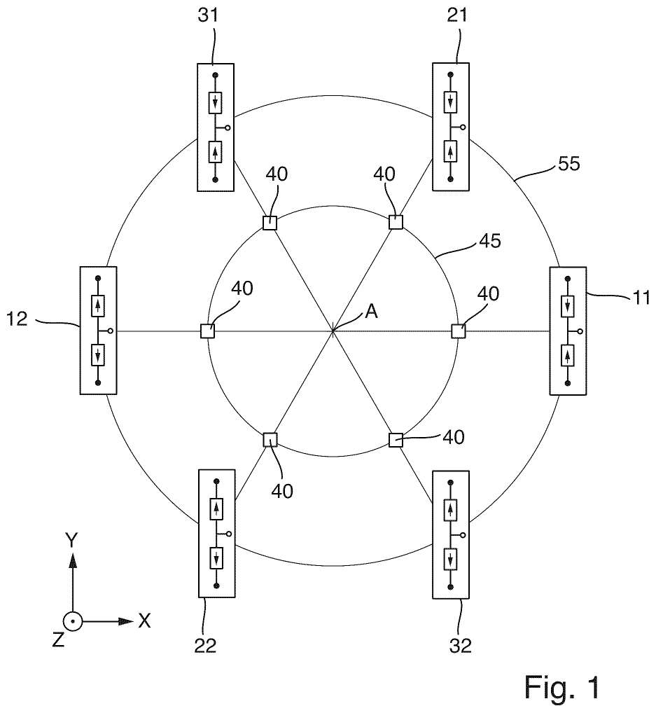

FIG. 1 shows a first example. A total of six Hall sensors 40 are arranged around a central axis A on a first circular path 45.

The Hall sensors 40 are arranged diametrically in pairs relative to axis A. The Hall sensors 40 have an equal distance from each other along the first circular path 45. In other words, the angle between two immediately adjacent Hall sensors 40 is 60°.

On a second circular track 55, the Z-TMR half-bridges 11 and 12, 21 and 22 as well as 31 and 33 are arranged diametrically in pairs relative to axis A. The half-bridges 11 and 12, 21 and 22 as well as 31 and 33 are at an equal distance from each other along the second circular runway 55. In other words, the angle between the two immediately adjacent half-bridges 11 and 12, 21 and 22 as well as 31 and 33 is 60° each.

The Hall sensors 40 and the half-bridges 11, 12, 21, 22, 31, 32 are each in the same angular position relative to axis A.

The radii of circular path 45 and circular path 55 are different.

In an example, the radii 45 and 55 are identical and the angular position of the half-bridges 11, 12, 21, 22, 31, 32 is different.

In an example, two Hall sensors 40 are arranged on the first circular path 45 and four half-bridges 11, 12, 21, 22 are arranged on the second circular path 55. It is understood that the distances on the circular path between immediately adjacent sensors are the same.

In another example, four Hall sensors 40 are arranged on the first circular path 45 and four half-bridges 11, 12, 21, 22 are arranged on the second circular path 55.

Although, for reasons of clarity, the Z-TMR resistors are shown in the longitudinal direction as a series connection in an X-Y plane, it is understood that the individual Z-TMR25 resistors of each branch are each formed in the Z direction, i.e., in the direction of an imaginary extension of axis A.

It should also be noted that the imaginary extension of axis A is preferably formed by the center point of the first circle and the center point of the second circle. In other words, the two circles have the same center point.

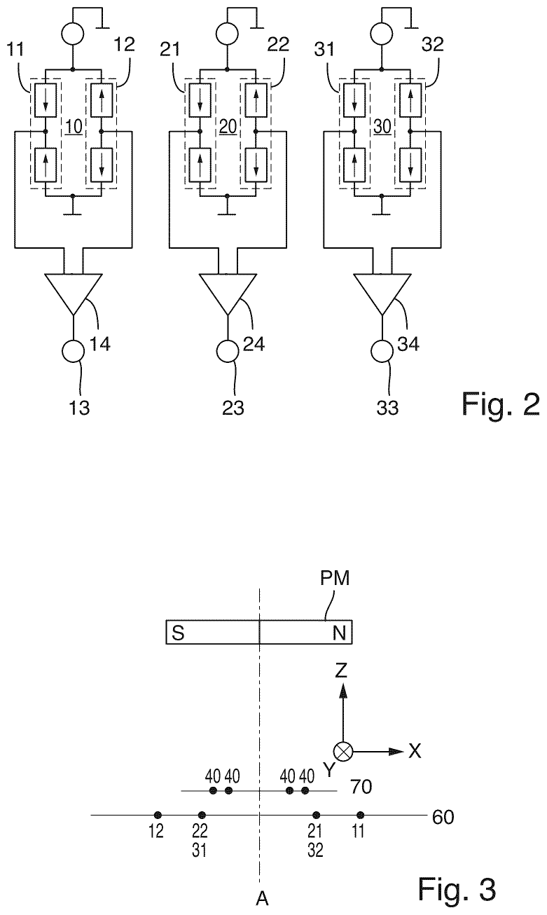

The illustration of FIG. 2 shows a circuitry-related example of the arrangement of FIG. 1.

The half-bridges, which are arranged diametrically in pairs relative to axis

A, are each connected to form full bridges. Half-bridges 11 and 12 form a full bridge 10, half-bridges 21 and 22 form a full bridge 20 and half-bridges 31 and 32 form a full bridge 30.

The bridge voltages from the three full bridges 10, 20 and 30 are three sensor signals and are further processed by the differential amplifiers 14, 24 and 34. The output signals of the differential amplifiers 14, 24 and 34 are provided as measurement signals 13, 23 and 33.

FIG. 3 shows an example of the arrangement. The Hall sensors 40 and the half-bridges 11, 12, 21, 22, 31, 32 are each arranged in the different planes 60 and 70.

Planes 60 and 70 are orthogonal to axis A and are spaced from each other in the Z direction. Axis A also forms the axis of rotation around which the permanent magnet PM is rotatable.

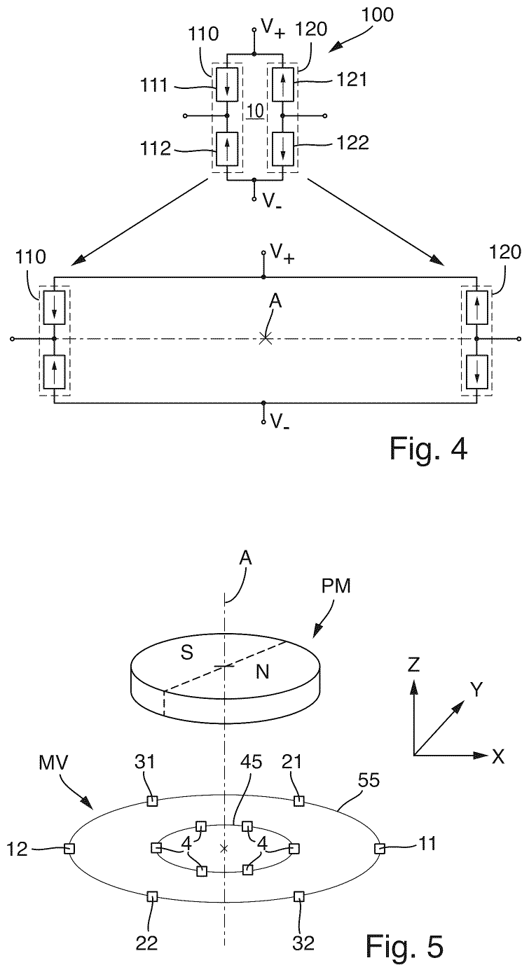

The illustration of FIG. 4 shows a schematic detail of a full bridge 100 formed of the two half-bridges 110 and 120.

The half-bridge 110 has two Z-TMR resistors 111 and 112 connected in series. The half-bridge 120 has two Z-TMR resistors 121 and 122 connected in series. The Z-TMR resistors 111 and 121 are connected in parallel with the supply input V+.

The Z-TMR resistors 112 and 122 are connected in parallel with the supply input V−. Geometrically, the half-bridges 110 and 120 are arranged in a plane orthogonal to axis A and are at an identical distance to the intersection of axis A with the plane.

FIG. 5 shows a schematic representation of the entire arrangement. A magnetic device MV having the diametrically magnetized disc magnet PM with the poles N and S is rotatably mounted around a virtual axis A.

The permanent magnet PM generates a magnetic field with the magnetic field components X, Y, Z. The orientation of axis A and the Z direction are parallel to each other. Twelve magnetic field sensors of two different types are arranged in the measuring device.

The six Hall sensors 4 are arranged on a circular path 45. The half-bridges 11, 12, 31, 32, 21 and 22 are arranged on a circular path 55. The circular paths 45 and 55 lie in a plane orthogonal to axis A and are spaced in the Z-direction from the permanent magnet PM.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A redundant magnetic field sensor array to measure an angle of rotation of a magnetic device, the magnetic device generates a magnetic field with magnetic field components in an X and a Y and a Z direction and is rotatable about an axis, the array comprising:
at least four individual magnetic field sensors, the magnetic field sensors are designed as at least two Hall sensors and as at least two Z-TMR Wheatstone bridges, the Hall sensors are formed as Hall plates in an X-Y plane and the two Z-TMR Wheatstone bridges each have two branches with half-bridges, the half-bridges including at least two Z-TMR resistors connected in series,
wherein the two branches of the Z-TMR Wheatstone bridges are positioned geometrically separated in two Z-TMR half-bridges,
wherein the Z-TMR half-bridges are arranged in pairs diametrically relative to the axis and a bridge voltage is applied to each of the respective bridge voltage taps as an output signal,
wherein the Z-TMR half-bridges are arranged on a first circular path, and
wherein the Hall plates and the Z-TMR half-bridges each measure the Z-component of the magnet field.

2. The redundant magnetic field sensor array according to claim 1, wherein six individual magnetic field sensors are provided, wherein the magnetic field sensors are designed as at least three Hall sensors and as at least three Z-TMR Wheatstone bridges, and wherein the three Z-TMR Wheatstone bridges each have two branches with half-bridges.

3. The redundant magnetic field sensor array according to claim 1, wherein the Z-TMR half-bridges and the Hall sensors are arranged concentrically around the axis and each lie in a plane, and wherein the plane is orthogonal to the axis.

4. The redundant magnetic field sensor array according to claim 1, wherein the sensors are arranged in two different planes, each of which is precisely orthogonally, or in a first approximation orthogonally, to the axis.

5. The redundant magnetic field sensor array according to claim 1, wherein the separate half-bridges, which are arranged in pairs diametrically opposite each other, are each tapped differentially using differential amplifiers, and the bridge voltages are provided as output signals.

6. The redundant magnetic field sensor array according to claim 1, wherein the half-bridges are arranged on the first circular path with a first radius and the Hall sensors are arranged on a second circular path with a second radius, wherein the first radius and the second radius differ.

7. The redundant magnetic field sensor array according to claim 6, wherein the first radius is greater than the second radius.

8. The redundant magnetic field sensor array according to claim 6, wherein the first radius and the second radius are arranged in the same plane or, in a first approximation, in the same plane.

9. The redundant magnetic field sensor array according to claim 1, wherein the half-bridges of different Z-TMR Wheatstone bridges are directly adjacent to each other on the first path.

10. The redundant magnetic field sensor array according to claim 1, wherein the magnetic field sensors are arranged along a single circular path.

11. The redundant magnetic field sensor array according to claim 1, wherein the two Z-TMR resistors connected in series in each branch have a mutually antiparallel measuring direction.

12. The redundant magnetic field sensor array according to claim 11, wherein the antiparallel measuring direction of the Z-TMR resistors of the two branches of the respective Z-TMR Wheatstone bridge is different from each other.

13. The redundant magnetic field sensor array according to claim 1, wherein the Z-TMR resistors are formed in the Z-direction.

14. The redundant magnetic field sensor array according to claim 1, wherein the branches of the Z-TMR Wheatstone bridges are connected to inputs of a differential amplifier.

15. The redundant magnetic field sensor array according to claim 1, wherein the distance between the two half-bridges of a branch, which are arranged diametrically on the first circle, is in a range between 0.2 mm and 10 mm or is greater than 0.2 mm.

16. The redundant magnetic field sensor array according to claim 1, wherein the distance between the two half-bridges of a branch, which are arranged diametrically on the first circle, is five times greater than the extension of one of the half-bridge elements in the direction of the respective longest extension.
